(19) United States
(12) Patent Application Publication
(10) Pub. No.: US 2025/0157840 A1
(43) Pub. Date: May 15, 2025

(54) TRANSPORT SYSTEM

(71) Applicant: Murata Machinery, Ltd., Kyoto-shi, Kyoto (JP)

(72) Inventor: Toma MIYAMURA, Ise-shi (JP)

(21) Appl. No.: 18/839,500

(22) PCT Filed: Mar. 9, 2023
(86) PCT No.: PCT/JP2023/009125

§ 371 Date: Aug. 19, 2024

(30) Foreign Application Priority Data
Apr. 19, 2022 (JP) 2022-068911

(51) Int. Cl. H01L 21/677

(52) U.S. Cl. CPC H01L 21/67706; H01L 21/67733

(57) ABSTRACT

A transport system includes an overhead transport vehicle to convey an article, a traveling path on which the overhead transport vehicle travels, and a reset signal generator to output a reset signal enabling the overhead transport vehicle to restart. The overhead transport vehicle includes a gripper, a lifting and lowering mechanism, a communication module to transmit an interlock signal, and a controller configured or programmed to control an operation of the overhead transport vehicle and to reset the interlock signal when a reset signal is input to the controller. When the gripper is located at a position other than a starting point, the controller is configured or programmed to not reset the interlock signal until the gripper rises to a position not interfering with the peripheral device.

### BACKGROUND OF THE INVENTION

### 1. Field of the Invention

The present invention relates to transport systems.

### 2. Description of the Related Art

In semiconductor manufacturing plants and other facilities, transport systems with transport devices are used to automatically convey products to be manufactured. For example, Japanese Unexamined Patent Publication No. 2017-154869 discloses a transfer device configured to use a drive medium to move a movable part. This transfer device includes a detection unit configured to monitor current flowing in a current path and generate a signal by detecting that the current has dropped to a value equal to or less than a predetermined value, and a control unit configured to store the fact that the signal has been generated when the signal has been generated, stop movement of the movable part while the signal is stored and display or report the fact that the signal has been generated, and by receiving an abnormality reset command from the operator, cause the detection unit to re-detect whether the current is equal to or less than the predetermined value, and lift the memory of the signal in a case where the current exceeds the predetermined value, and maintain the memory of the signal in a case where the current is equal to or less than the predetermined value.

In Japanese Unexamined Patent Publication No. 2017-154869, the above-described detection unit and the above-described control unit are included to stop the movement of the movable part when breakage of the drive medium is predicted, while the current continues to flow in the current path. When the operator inputs an abnormal reset command, the current flowing through the current path is detected again, and in a case where the current exceeds a predetermined value, the signal can be lifted to restore the movement of the movable part.

### SUMMARY OF THE INVENTION

For example, in a case where an overhead transport vehicle is used as a transport system in manufacturing plants, for example, semiconductor plants, the overhead transport vehicle conveys a conveyed object to a peripheral device, for example, a processing apparatus. In such a mode, it is essential to prevent interference of the overhead transport vehicle with the above-described peripheral device in order to ensure safe travel of the overhead transport vehicles. In a case where an operating state of peripheral devices at the time of resetting an abnormality that has occurred in an overhead transport vehicle or other device is not taken into consideration, there is a risk that preventing interference between the overhead transport vehicle and the peripheral device will not be adequately performed immediately after the abnormality is resolved or otherwise. This causes a concern that a safe travel of the overhead transport vehicle is threatened.

Example embodiments of the present invention provide transport systems each capable of performing safe travel of the overhead transport vehicle even in the presence of a peripheral device.

A transport system according to an example embodiment of the present disclosure includes an overhead transport vehicle to convey an article in an area where interference may occur with a peripheral device, a traveling path on which the overhead transport vehicle travels, and a reset signal generator to output a reset signal in response to an abnormal stop of the overhead transport vehicle, the reset signal enabling the overhead transport vehicle to restart, wherein the overhead transport vehicle includes a gripper to grip the article, a lifting and lowering mechanism to lift and lower the gripper, a communication module to transmit an interlock signal to the peripheral device during transfer of the article, and a controller configured or programmed to control an operation of the overhead transport vehicle and to reset the interlock signal when a reset signal is input to the controller, and when the gripper is located at a position other than a starting point, the controller is configured or programmed to not reset the interlock signal the gripper rises to a position not interfering with the peripheral device, even in a case where the reset signal has been input to the controller.

In a transport system according to an example embodiment of the present disclosure, in a case where the reset signal output in response to the abnormal stop of the overhead transport vehicle is input to the controller when the gripper is located at a position other than the starting point, the controller is configured programmed to hold the interlock signal until the gripper rises to a position where the gripper does not interfere with the peripheral device. This restricts or stops the operation of the peripheral device, even after the controller receives the reset signal, until the gripper rises to a position where the gripper does not interfere with peripheral device. This can prevent the peripheral device from interfering with the overhead transport vehicle during a return of the gripper to the starting point, thereby enabling safe travel of the overhead transport vehicle even in the presence of the peripheral device.

When the gripper is located at a position other than the starting point, the above-described controller need not reset the interlock signal until the gripper returns to the starting point. In this case, it is reliably possible to prevent the peripheral device from interfering with the overhead transport vehicle during the return of the gripper to the starting point.

The above-described overhead transport vehicle may further include a reset button included in the reset signal generator. In this case, a reset signal can be easily transmitted.

The above-described transport system may further include an abnormality detection sensor to detect an abnormality in the overhead transport vehicle. In this case, since it is possible to quickly detect the abnormality in the overhead transport vehicle, interference between the overhead transport vehicle and the peripheral device can be prevented favorably.

The peripheral device may include a processing device configured to process an article. Moreover, the peripheral device may include an overhead crane.

According to example embodiments of the present disclosure, transport systems capable of performing safe travel of the overhead transport vehicle even in the presence of a peripheral device can be provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a transport system according to an example embodiment of the present invention.

FIG. 2 is a front view of a portion of the transport system.

FIG. 3 is a flowchart illustrating a transfer method of a FOUP between the transport system and a semiconductor processing apparatus.

FIG. 4 is a flowchart explaining how the transport system returns when an abnormality in the overhead transport vehicle is detected with the gripper located at a position other than the starting point.

FIG. 5 is a schematic diagram illustrating a state of the overhead transport vehicle in each timing.

### DETAILED DESCRIPTION OF THE EXAMPLE EMBODIMENTS

Example embodiments of the present invention will now be described in detail with reference to the attached drawings. In description of the drawings, same or equivalent elements are designated by like reference signs, and duplicate description is omitted.

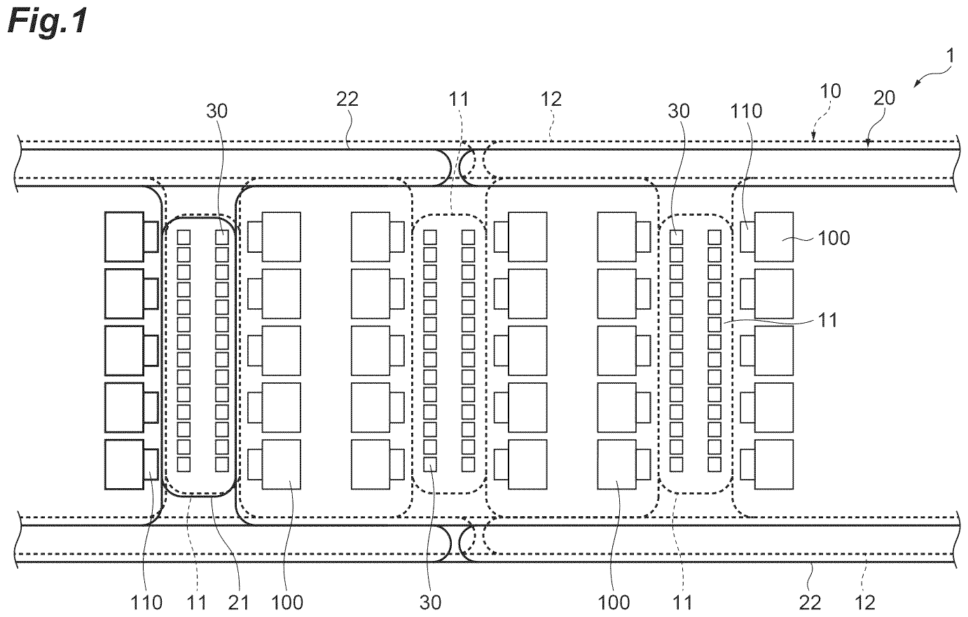

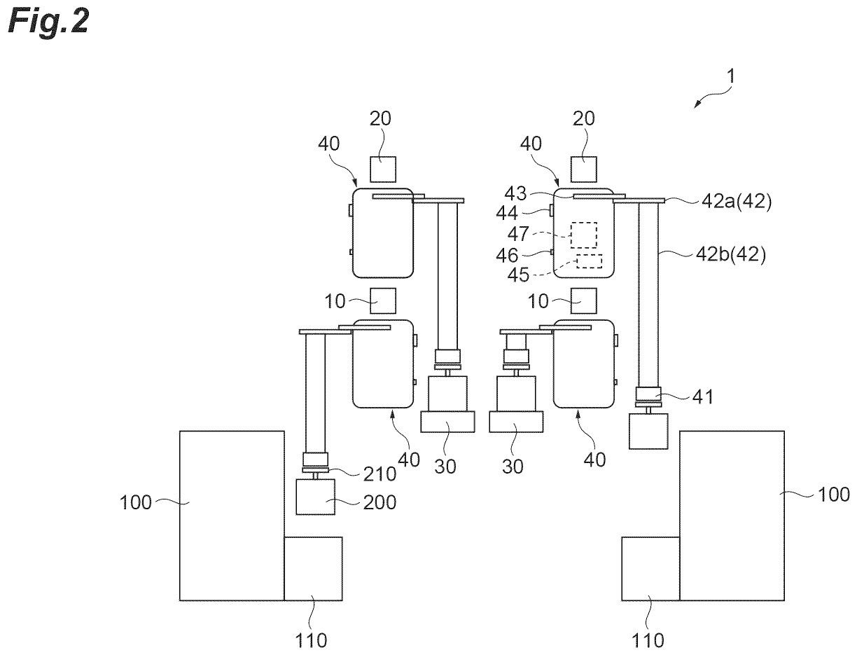

FIG. 1 is a plan view of a transport system according to the present example embodiment. FIG. 2 is a front view of a portion of the transport system. As illustrated in FIG. 1, a transport system 1 is a system installed in, for example, a semiconductor manufacturing plant equipped with a semiconductor processing apparatus 100, which is one of peripheral devices, the system conveying an article such as a FOUP (conveyed object) 200. The FOUP 200 is a container (FOUP: Front Opening Unified Pod) usable to store semiconductor wafers. The semiconductor processing apparatus 100 is processing apparatus for the above-described semiconductor wafers (for example, cleaning apparatus, etching apparatus, deposition apparatus, and the like) and includes a device port 110 to carry in and out the FOUP 200. The device port 110, for example, includes a communication module (not illustrated) configured to communicate with the transport system 1. The communication module, for example, exchanges interlock signals with an overhead transport vehicle 40, which is described later. In the present example embodiment, the interlock signal is a signal exchanged according to procedures specified in E84 of the semiconductor apparatus and materials international (SEMI) standards.

As illustrated in FIGS. 1 and 2, the transport system 1 includes a first track 10, a second track 20, a storage shelf 30, and a plurality of overhead transport vehicles 40. In the transport system 1, the overhead transport vehicle 40 moving along the first track 10 or the second track 20, for example, allows the FOUP 200 to be transferred to the device port 110 of the semiconductor processing apparatus 100. Although not illustrated, the transport system 1 further includes, for example, a HOST and a material control system (MCS) as control devices. Each of the HOST and the MCS is an electronic control unit constituted by a central processing unit (CPU), a read only memory (ROM), a random access memory (RAM), and the like, for example. The HOST is an upper-level controller. The HOST can be a manufacturing execution system (MES). The HOST outputs signals including various kinds of commands such as a conveyance command or a traveling command (hereinafter simply referred to as “command”) to the MCS. When obtaining a command from the HOST, the MCS outputs the command to the overhead transport vehicle 40 and other devices at a predetermined timing via a controller 47, which will be described later.

The first track 10 is a structure (traveling path) on which the overhead transport vehicle 40 travels, and the first track 10 is suspended from the ceiling. In the present example embodiment, the transport system 1 defines or includes a plurality of systems (bays). The transport system 1 includes a plurality of intrabay routes, which are traveling paths within bays, and interbay routes, which are traveling paths connecting different bays. The intrabay routes are disposed along a plurality of the device ports 110. The first track 10 includes intrabay tracks 11 disposed in a plurality of the intrabay routes and an interbay track 12 disposed in the interbay route. The intrabay track 11 is a track passing near the storage shelf 30, the semiconductor processing apparatus 100, and the like and is set such that the overhead transport vehicle 40 travels one way clockwise. Similar to the intrabay track 11, the interbay track 12 is also set such that the overhead transport vehicle 40 travels one way clockwise. In the first track 10, settings may be made such that the overhead transport vehicle 40 travels one way counterclockwise.

The second track 20 is a structure (traveling path) on which the overhead transport vehicle 40 travels, and the second track 20 is suspended from the ceiling. The second track 20 includes an intrabay track 21 disposed in a portion of the intrabay routes and an interbay track 22 disposed in the interbay route. The intrabay track 21 is a track passing near the storage shelf 30, the semiconductor processing apparatus 100, and the like and is set such that the overhead transport vehicle 40 travels one way clockwise. Similar to the intrabay track 21, the interbay track 22 is also set such that the overhead transport vehicle 40 travels one way clockwise. In the second track 20, settings may be made such that the overhead transport vehicle 40 travels one way counterclockwise.

As illustrated in FIG. 2, the first track 10 and the second track 20 are disposed in parallel with each other in the up-down (vertical) direction. The first track 10 is positioned below the second track 20. In other words, the second track 20 is located above the first track 10. In FIG. 1, the first track 10 is illustrated as a dashed line and the second track 20 is illustrated as a solid line.

As illustrated in FIG. 1, in the transport system 1, the respective device ports 110 of the semiconductor processing apparatuses 100 are disposed outside the intrabay route, along a direction in which the first track 10 and the second track 20 extend. Each of the device ports 110 is provided to be positioned on one side of and below the first track 10 and the second track 20 that are disposed in parallel with each other in the up-down direction.

The device ports 110 include the FOUPs 200 that have been transferred from the overhead transport vehicle 40 placed thereon, and the FOUPs 200 are transferred to the semiconductor processing apparatuses 100. When semiconductor wafers accommodated in the FOUPs 200 are processed by the semiconductor processing apparatuses 100, the FOUPs 200 are transferred from the semiconductor processing apparatuses 100, and the device ports 110 are in a state of having the FOUPs 200 placed thereon.

The storage shelf 30 is a structure that stores therein the FOUP 200. The plurality of storage shelves 30 each support the FOUP 200. The storage shelves 30 are suspended from the ceiling, for example. Each storage shelf 30 can be an overhead buffer (OHB). A region on the storage shelf 30 can have the FOUP 200 placed thereon. That region on the storage shelf 30 is a temporary storage region onto which the overhead transport vehicle 40 stopped on the first track 10 and the second track 20 can transfer the FOUP 200.

As illustrated in FIG. 2, the storage shelves 30 are provided below the first track 10 and the second track 20 and on the other side being opposed to one side on which the device ports 110 are provided with the first track 10 and the second track 20 interposed therebetween. Specifically, when viewed from the vertical direction, the storage shelves 30 are provided on the side opposed to the device ports 110 with the first track 10 and the second track 20 interposed therebetween. The storage shelves 30 are provided inside the intrabay route having a loop shape.

The overhead transport vehicle 40 is a device configured to convey the FOUP 200 in an area where interference may be occurred with a peripheral device, for example, the storage shelf 30 or the semiconductor processing apparatus 100, and moves along the first track 10 or the second track 20. Examples of the overhead transport vehicle 40 include a crane suspended from a ceiling, an overhead hoist transfer (OHT), and the like. The overhead transport vehicle 40 includes a gripper 41, a lifting and lowering mechanism 42, a moving mechanism 43, an abnormality detection sensor 44, a communication module 45, a reset button 46 (reset signal generator), and a controller 47.

The gripper 41 is a device configured to grip and release the FOUP 200. The gripper 41 can grip a flange portion 210 of the FOUP 200. When the overhead transport vehicle 40 acquires the FOUP 200 from the device port 110 or the storage shelf 30, the gripper 41 grips the flange portion 210 of the FOUP 200. When the overhead transport vehicles 40 places the FOUP 200 onto the device port 110 or the storage shelf 30, the gripper 41 releases the flange portion 210 of the FOUP 200.

The lifting and lowering mechanism 42 is a device (hoist, or the like) configured to lift and lower the gripper 41 in the vertical direction. The lifting and lowering mechanism 42 can lift and lower the gripper 41 in the vertical direction. The lifting and lowering mechanism 42 includes a winding mechanism 42a and a belt 42b. The winding mechanism 42a is supported by the moving mechanism 43. The winding mechanism 42a is a device configured to wind up and wind down the belt 42b in the vertical direction. The winding mechanism 42a can wind up and wind down the belt 42b in the vertical direction. The belt 42b is suspended from the winding mechanism 42a. The belt 42b supports the gripper 41 at the lower end thereof. The lifting and lowering mechanism 42 can wind up and wind down the FOUP 200 gripped by the gripper 41 for a distance at least allowing the FOUP 200 to reach the device port 110 and the storage shelf 30.

The moving mechanism 43 is a device configured to move the gripper 41 and the lifting and lowering mechanism 42 along the sides of the overhead transport vehicle 40. Specifically, the moving mechanism 43 can move the gripper 41 and the lifting and lowering mechanism 42 from the overhead transport vehicle 40 in the horizontal direction orthogonal to the traveling direction of the overhead transport vehicle 40. The moving mechanism 43 can move the gripper 41 and the lifting and lowering mechanism 42 to above each of the device port 110 and the storage shelf 30. When the FOUP 200 is gripped by the gripper 41, the moving mechanism 43 can move the FOUP 200 to or from above the device port 110 and the storage shelf 30 in the vertical direction. In the present example embodiment, the gripper 41 may be considered to be at the starting point when the belt 42b is fully wound up. Therefore, the gripper 41 is considered to be at the starting point when the belt 42b is fully wound up, even when the gripper 41 and the lifting and lowering mechanism 42 are moved sideways by the moving mechanism 43.

The respective overhead transport vehicles 40 that stop at the same position in the traveling direction on each of the first track 10 and the second track 20 can transfer the FOUPs 200 to both the device port 110 and the storage shelf 30, which are positioned on the side of and below the first track 10 and the second track 20. In other words, each of the overhead transport vehicles 40 can transfer the FOUP 200 to the same device port 110 and the same storage shelf 30. Specifically, both of the overhead transport vehicle 40 in the first track 10 and the overhead transport vehicle 40 in the second track 20 can deliver (transfer) the FOUP 200 to and from the device port 110. Also, both of the overhead transport vehicle 40 in the first track 10 and the overhead transport vehicle 40 in the second track 20 can deliver the FOUP 200 to and from the storage shelf 30.

The overhead transport vehicle 40 moves the FOUP 200 upward above each of the device port 110 and the storage shelf 30, by operating the moving mechanism 43 from a state where the gripper 41 grips the flange portion 210 of the FOUP 200 directly under the first track 10 and the second track 20. Subsequently, the overhead transport vehicle 40 operates the winding mechanism 42a to wind down the belt 42b, thereby lowering the FOUP 200 to place the FOUP 200 on the device port 110 or on the storage shelf 30. As described above, the overhead transport vehicle 40 transfers (places) the FOUPs 200 to (on) the device port 110 and the storage shelf 30.

Each of the overhead transport vehicles 40 causes the gripper 41 to grip the flange portion 210 of the FOUP 200 placed on the device port 110 or on the storage shelf 30. Subsequently, each of the overhead transport vehicles 40 causes the winding mechanism 42a to operate to wind up the belt 42b, thereby lifting the FOUP 200. Subsequently, each of the overhead transport vehicles 40 causes the moving mechanism 43 to operate to move the FOUP 200 to directly below the first track 10 and the second track 20. As described above, each of the overhead transport vehicles 40 transfers (acquire) the FOUP 200 from the device port 110 or the storage shelf 30.

An abnormality detection sensor 44 is a sensor configured to detect an abnormality in the overhead transport vehicle 40. The abnormality detection sensor 44 detects, for example, whether the overhead transport vehicle 40 is operating normally. For example, if the movement of the overhead transport vehicle 40, gripping and release of the gripper 41, the operation of the lifting and lowering mechanism 42, and the operation of the moving mechanism 43 are not carried out according to the commands from the above-described control device, the abnormality detection sensor 44 detects that an abnormality occurs in the overhead transport vehicle 40. If there is a problem with power supply or signal transmission to the overhead transport vehicle 40, the abnormality detection sensor 44 may detect that an abnormality has occurred in the overhead transport vehicle 40. When detecting an abnormality in the overhead transport vehicle 40, the abnormality detection sensor 44 notifies the controller 47 of a signal (abnormality detection signal) indicating that the abnormality detection sensor 44 has detected the abnormality.

The communication module 45 can communicate with the semiconductor processing apparatus 100 via, for example, wireless communication. The communication module 45 transmits an interlock signal to the semiconductor processing apparatus 100, for example, during the transfer of the FOUP 200. The transmission of such an interlock signal restricts the operation of the semiconductor processing apparatus 100 (in particular, the operation of the device port 110). This can prevent interference (contact, collision, and the like) at unintended points between the gripper 41, the lifting and lowering mechanism 42, or the like of the overhead transport vehicle 40 and the semiconductor processing apparatus 100.

The reset button 46 is a portion (reset signal generator) usable to transmit a reset signal that enables the overhead transport vehicle 40 to restart, and is provided at a predetermined position on the overhead transport vehicle 40. The reset button 46 is pressed, for example, when the overhead transport vehicle 40 is restarted after the overhead transport vehicle 40 stopped abnormally and the abnormality occurring in the overhead transport vehicle 40 or the like has been resolved. Therefore, the reset button 46 can be said to be a part that is pressed in response to the abnormal stop of the overhead transport vehicle 40, and the reset signal can be said to be a signal that is transmitted in response to the abnormal stop of the overhead transport vehicle 40. The reset button 46 is pressed, for example, by an operator or a work robot that has resolved an abnormality occurring in the overhead transport vehicle 40 or the like. When the reset button 46 is pressed, a reset signal is transmitted to the communication module 45 and/or the controller 47. The reset signal restarts (resets) at least some commands (for example, transport commands), signals (for example, interlock signals), and the like held by the overhead transport vehicle 40. Therefore, in the present example embodiment, the restarting of the overhead transport vehicle 40 by the reset signal does not necessarily restart the entire overhead transport vehicle 40, and the reset signal at least includes a signal to reset the interlock signal that has been transmitted to the semiconductor processing apparatus 100.

The reset button 46 does not have to be pressed directly by the operator or the work robot. For example, the reset button 46 may be pressed via a remote controller, application, and the like for the overhead transport vehicle 40. Alternatively, when the above-described control device determines that the abnormality in the overhead transport vehicle 40 has been resolved, the reset signal may be output without the reset button 46 being pressed in response to the command from the above-described control device. In these cases, the reset button 46 need not be provided on the overhead transport vehicle 40, and instead the above-described reset signal generator may be provided on a device (for example, the above-described remote controller) other than the overhead transport vehicle 40.

The controller 47 is a device configured or programmed to control the operation of the overhead transport vehicle 40. The controller 47 may include an electronic control unit defined by or including a central processing unit (CPU), a read only memory (ROM), a random access memory (RAM), and the like. The controller 47 is configured or programmed to control the travel of the overhead transport vehicle 40, the operation of the gripper 41, the operation of the lifting and lowering mechanism 42, the operation of the moving mechanism 43, and the communication with the semiconductor processing apparatus 100 according to the commands received from the above-described control device.

When an abnormality occurs in the overhead transport vehicle 40 (i.e., when an abnormality detection signal is input to the controller 47), the controller 47 stops the operation of the overhead transport vehicle 40 in an emergency. At this time, the controller 47 stops not only the movement of the overhead transport vehicle 40 but also the operations of the gripper 41, the lifting and lowering mechanism 42, and the moving mechanism 43 in an emergency.

When a reset signal transmitted due to the occurrence of an abnormality in the overhead transport vehicle 40 when the gripper 41 is at the starting point (position not interfering with the devices) is input to the controller 47, the controller 47 resets the interlock signal that has been transmitted to the semiconductor processing apparatus 100 (stops sending the interlock signal). Therefore, when the gripper 41 is positioned at the starting point, the operation restriction on the semiconductor processing apparatus 100 caused by the overhead transport vehicle 40 is lifted in response to the transmission of the reset signal. This allows the semiconductor processing apparatus 100 to be in a state of being able to perform the following operations.

On the other hand, when the abnormality in the overhead transport vehicle 40 is resolved in a state in which the gripper 41 is located at a position other than the starting point and a reset signal is input to the controller 47, the controller 47 does not reset the interlock signal that has been transmitted to the semiconductor processing apparatus 100. In this case, the overhead transport vehicle 40 continues sending the same interlock signal as that before the abnormality occurred to the semiconductor processing apparatus 100. Therefore, even if the reset signal is transmitted when the gripper 41 is located at a position other than the starting point, the operation restriction on the semiconductor processing apparatus 100 caused by the overhead transport vehicle 40 is not lifted.

After the reset signal is input to the controller 47 when the gripper 41 is located at a position other than the starting point, a signal (return signal) to return the gripper 41 to the starting point is input to the controller 47. This allows the controller 47 to operate the lifting and lowering mechanism 42 and/or the moving mechanism 43 to return the gripper 41 to the starting point. After the gripper 41 returns to the starting point, the interlock signal can be reset by the controller 47. Therefore, after the gripper 41 returns to the starting point, the controller 47 resets the interlock signal that has been transmitted to the semiconductor processing apparatus 100, and the operation restriction on the semiconductor processing apparatus 100 caused by the overhead transport vehicle 40 is lifted. This can prevent interference (contact, collision, and the like) at unintended points between the gripper 41, the lifting and lowering mechanism 42, or the like of the overhead transport vehicle 40 and the semiconductor processing apparatus 100 immediately after return of the overhead transport vehicle 40 or other timing. The return signal is input, for example, by operation of a remote controller or the like by the operator.

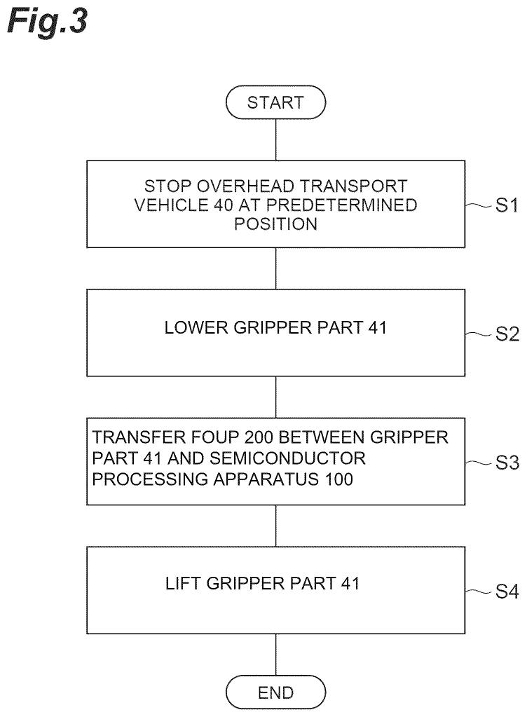

Next, with reference to FIG. 3, the transfer method of FOUPs between the transport system according to the present example embodiment and the semiconductor processing apparatus is described. FIG. 3 is a flowchart illustrating a transfer method of the FOUP between the transport system and the semiconductor processing apparatus.

As illustrated in FIG. 3, first, the overhead transport vehicle 40 is stopped at a predetermined position (step S1). In step S1, the overhead transport vehicle 40 gripping the FOUP 200 is stopped in the vicinity (predetermined position) of the semiconductor processing apparatus 100. Alternatively, in step S1, the overhead transport vehicle 40 in a state of not gripping the FOUP 200 is stopped at a predetermined position of the semiconductor processing apparatus 100.

Next, the gripper 41 is lowered (step S2). In step S2, the gripper 41 is moved to a position other than the starting point so that the moving mechanism 43 is moved to move the FOUP 200 above the device port 110. The winding mechanism 42a is then operated to wind down the belt 42b, thereby lowering the gripper 41 gripping the FOUP 200. Alternatively, in step S2, the gripper 41 not gripping the FOUP 200 is lowered by winding down the belt 42b.

Next, the FOUP 200 is transferred between the gripper 41 and the semiconductor processing apparatus 100 (step S3). In step S3, the gripping of the FOUP 200 by the gripper 41 is released, and thereby the FOUP 200 is placed on the device port 110 of the semiconductor processing apparatus 100. Alternatively, in step S3, the gripper 41 grips the flange portion 210 of the FOUP 200 positioned on the device port 110 of the semiconductor processing apparatus 100.

Next, the gripper 41 is lifted (step S4). In step S4, the winding mechanism 42a is operated to wind up the belt 42b, and thereby the gripper 41 is lifted. When the gripper 41 grips the FOUP 200, the moving mechanism 43 is operated to move the FOUP 200 to directly under the first track 10 and the second track 20. As described above, the overhead transport vehicle 40 transfers or receives the FOUP 200 to the device port 110 or from the device port 110. The gripper 41 is then returned to the starting point.

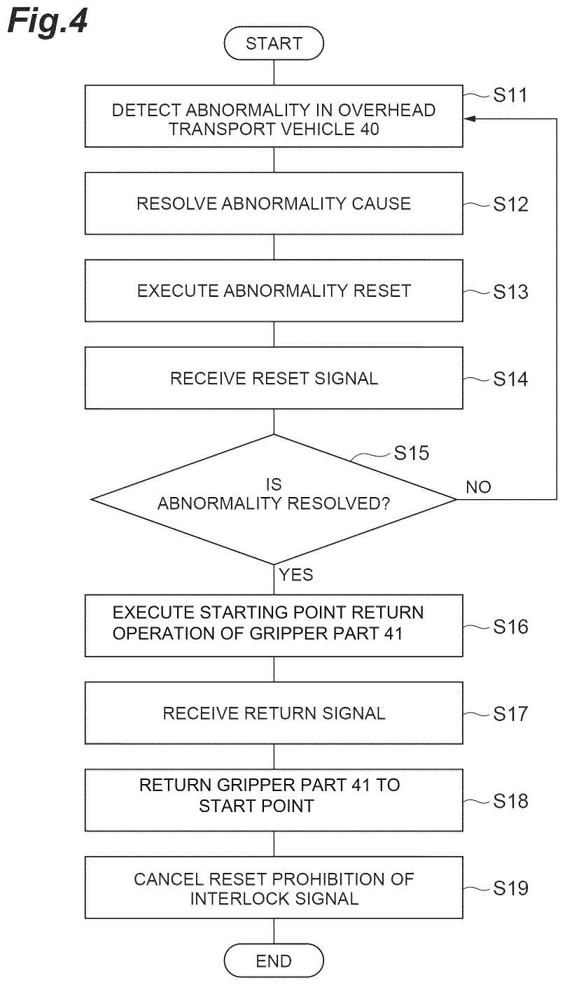

With reference to FIG. 4, the following describes the operation of the transport system 1 when an abnormality is detected in the overhead transport vehicle 40 between the start of step S1 and the completion of step S4. FIG. 4 is a flowchart explaining how the transport system returns when an abnormality is detected in an overhead transport vehicle with the gripper located at a position other than the starting point.

As illustrated in FIG. 4, between the start of step S1 and the completion of step S4 (during the transfer of FOUP 200), an abnormality in the overhead transport vehicle 40 is detected (step S11). In step S11, during the transfer of the FOUR 200, the abnormality detection sensor 44 detects an abnormality in the overhead transport vehicle 40 and notifies the controller 47 with an abnormality detection signal. The controller 47 notified of the abnormality detection signal stops the overhead transport vehicle 40 in an emergency. At this time, the gripper 41 is located at a position other than the starting point.

Next, a cause of abnormality is resolved (step S12). In step S12, the cause of abnormality in the overhead transport vehicle 40 is resolved by an operator, a work robot, and the like. In step S12, if no abnormality occurs in the overhead transport vehicle 40 (for example, abnormality detected by the abnormality detection sensor 44 due to an abnormality in a device different from the overhead transport vehicle 40), the reason why the abnormality detection signal was transmitted may be resolved.

Next, an abnormality reset is performed (step S13). In step S13, the reset signal is transmitted when an operator, a work robot, and the like presses the reset button 46. This causes the reset signal to be input to the controller 47 (step S14). At this time, the controller 47 does not reset the interlock signal to be transmitted to the semiconductor processing apparatus 100.

Next, whether the abnormality in the overhead transport vehicle 40 has been resolved is determined (step S15). In step S15, the abnormality detection sensor 44 again detects the presence or absence of an abnormality in the overhead transport vehicle 40. When it is determined that the abnormality in the overhead transport vehicle 40 has not been resolved (step S15: NO), step S12 is performed again.

Next, when it is determined that the abnormality in the overhead transport vehicle 40 has been resolved (step S15: YES), an operation of returning to the starting point of the gripper 41 is performed (step S16). In step $16, a return signal is transmitted to return the gripper 41 to the starting point, for example, by operation of a remote control by the operator or the like. This causes a return signal to be input to the controller 47 (step S17). In step S17, based on the return signal, the controller 47 allows the lifting and lowering mechanism 42 and/or the moving mechanism 43 to operate. At this time, the controller 47 continues to prohibit resetting the interlock signal. This returns the gripper 41 to the starting point (step S18), with the operation of the semiconductor processing apparatus 100 restricted.

Next, after step S18, the prohibition of resetting the interlock signal is lifted (step S19). This causes the operation restriction on the semiconductor processing apparatus 100 caused by the overhead transport vehicle 40 to be lifted. As described above, the return of the transport system 1 when an abnormality is detected in the overhead transport vehicle 40 with the gripper 41 located at a position other than the starting point completes.

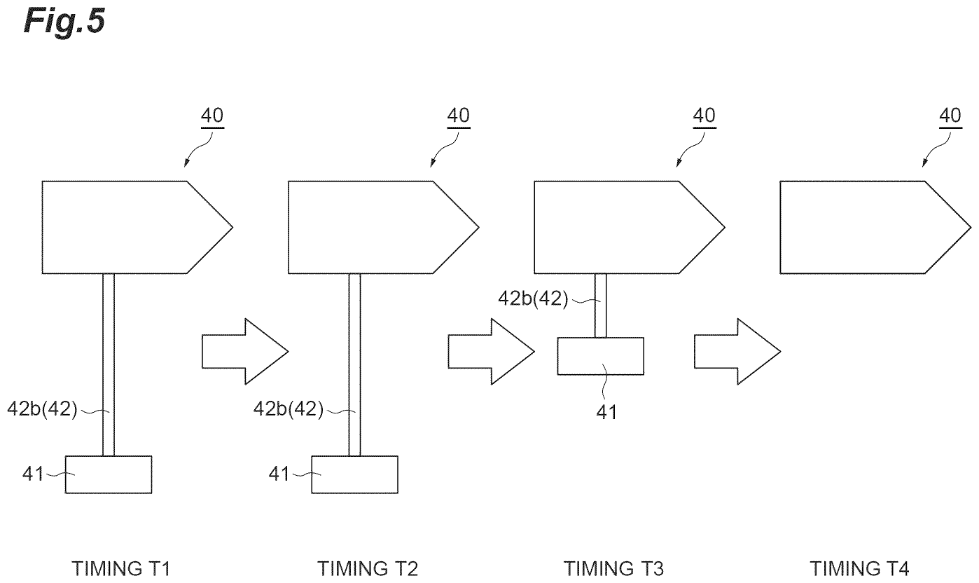

The operations and effects produced by the transport system 1 according to the present example embodiment described above will be explained with reference to FIG. 5. FIG. 5 is a schematic diagram illustrating a state of the overhead transport vehicle at each timing. In FIG. 5, timing T1 indicates the state of the overhead transport vehicle 40 in step S11 above. Timing T2 indicates the state of the overhead transport vehicle 40 in step S14 above. Timing T3 indicates the state of the overhead transport vehicle 40 in step S18 above. Timing T4 indicates the state of the overhead transport vehicle 40 in step S19 above.

In the present example embodiment, when a reset signal is input to the controller 47, the reset signal being transmitted due to the occurrence of an abnormality in the overhead transport vehicle 40 with the gripper 41 located at a position other than the starting point, the controller 47 does not reset the interlock signal until the gripper 41 returns to the starting point. In other words, from timing T2 to timing T4 indicated in FIG. 5 (i.e., from steps S14 to S19 above), the controller 47 prohibits resetting the interlock signal. Therefore, from timing T2 to timing T4, the transmission of the interlock signal by the communication module 45 to the semiconductor processing apparatus 100 is maintained. This restricts or stops the operation of the semiconductor processing apparatus 100 until the gripper 41 returns to the starting point after the reset signal is input to the controller 47. Thus, the interference of the semiconductor processing apparatus 100 with the overhead transport vehicle 40 before the gripper 41 returns point can be prevented. Therefore, using the transport system 1 according to the present example embodiment enables safe travel of the overhead transport vehicle 40 even in the presence of peripheral device, for example, the semiconductor processing apparatus 100.

Unlike the present example embodiment, in a transport system in which resetting the interlock signal is not prohibited, the operation restriction on the semiconductor processing apparatus caused by the overhead transport vehicle is lifted after timing T2 indicated in FIG. 5. In other words, after timing T2, the semiconductor processing apparatus can operate. As a result, interference may occur at unintended points between the gripper and the semiconductor processing apparatus immediately after timing T2, at timing T3, or other timing. However, according to the present example embodiment, as described above, it is possible to prevent the semiconductor processing apparatus 100 from interfering with the overhead transport vehicle 40.

In the present example embodiment, the overhead transport vehicle 40 includes a reset button 46. Therefore, the overhead transport vehicle 40 can easily transmit a reset signal.

In the present example embodiment, the overhead transport vehicle 40 includes the abnormality detection sensor 44 configured to detect an abnormality in the overhead transport vehicle 40. This makes it possible to quickly detect an abnormality in the overhead transport vehicle 40, and to favorably prevent interference between the overhead transport vehicle 40 and the semiconductor processing apparatus 100.

However, the present disclosure is not limited to the above-described example embodiments. Example embodiments of the present disclosure can be further modified in the scope of not departing from the spirit thereof. For example, in the above-described example embodiments, the transport system may be installed in a semiconductor processing plant, but this is not limiting and may be installed in other facilities. In this case, a processing apparatus configured to perform some kind of processing on articles as a peripheral device is installed in other facilities. In other facilities, an interlock signal is not limited to the E84 signal.

In the above-described example embodiments, an example of the peripheral device is a semiconductor processing apparatus, but this is not limiting. The peripheral device may be, for example, an overhead crane that can be moved to an area where interference may be occurred with an overhead transport vehicle, or an overhead crane that is installed in the above-described area. The peripheral device is not limited to one type. There may be two or more types of peripheral devices positioned in the area where interference may be occurred with the overhead transport vehicle.

In the above-described example embodiments, the overhead transport vehicle includes a reset button, but this is not limiting, and the transport system may include a reset signal generator. For example, a reset signal generator such as a reset button may be provided outside the overhead transport vehicle, or the reset signal generator may be a diagram to transmit a reset signal, the diagram being displayed via an application on a portable device such as a tablet.

In the above-described example embodiments, the overhead transport vehicle includes an abnormality detection sensor, but this is not limiting, and the transport system may include an abnormality inspection system. For example, the transport system may be provided with a plurality of cameras, detectors, and the like as abnormality detection sensors.

In the above-described example embodiments, when an abnormality is detected in the overhead transport vehicle with the gripper located at a position other than the starting point, the controller does not always reset the interlock signal until the gripper returns to the starting point, but this is not limiting. Depending on the installation environment of the transport system, when an abnormality is detected in the overhead transport vehicle with the gripper located at a position other than the starting point, the controller may be set not to prohibit resetting the interlock signal until the gripper returns to the starting point. The setting of the controller of the interlock signal resetting prohibition function may be optionally switched. In this case, the transport system can be installed regardless of the installation environment and other factors.

In the above-described example embodiments, when an abnormality is detected in the overhead transport vehicle with the gripper located at a position other than the starting point, the controller always prohibits resetting the interlock signal until the gripper returns to the starting point, but this is not limiting. For example, depending on the layout of the transport system, the interlock signal need not be reset until the gripper rises to a position not interfering with a peripheral device (position at which an arbitrary distance from the starting point has been reached).

In the above-described example embodiments, the first track and the second track may be disposed in parallel with each other in the up-down (vertical) direction, but this is not limiting. Only one track may be provided for the overhead transport vehicle, or three or more tracks may be arranged side by side or in parallel. The tracks may be arranged such that only some of the plurality of tracks overlap in the up-down (vertical) direction, or that the tracks with different heights does not overlap in the up-down (vertical) direction.

In the above-described example embodiments, when viewed from the vertical direction, the plurality of storage shelves are provided on the side opposed to the plurality of device ports with the first track and the second track interposed therebetween, but this is not limiting. The processing ports and storage shelves may be located on the same side with respect to the tracks. The storage shelves may be provided inside of the intrabay route having a loop shape or may be provided outside the intrabay route.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7. A transport system comprising:
an overhead transport vehicle to convey an article in an area where interference may occur with a peripheral device;
a traveling path on which the overhead transport vehicle travels; and
a reset signal generator to output a reset signal in response to an abnormal stop of the overhead transport vehicle, the reset signal enabling the overhead transport vehicle to restart; wherein
the overhead transport vehicle includes:
a gripper to grip the article;
a lifting and lowering mechanism to lift and lower the gripper;
a communication module to transmit an interlock signal to the peripheral device during transfer of the article; and
a controller configured or programmed to control an operation of the overhead transport vehicle and to reset the interlock signal when a reset signal is input to the controller; and
when the gripper is located at a position other than a starting point, the controller is configured or programmed to not reset the interlock signal until the gripper rises to a position not interfering with the peripheral device, even in a case where the reset signal has been input to the controller.

8. The transport system according to claim 7, wherein, when the gripper is located at a position other than a starting point, the controller is configured or programmed to not reset the interlock signal until the gripper returns to the starting point.

9. The transport system according to claim 7, wherein the overhead transport vehicle includes a reset button included in the reset signal generator.

10. The transport system according to claim 7, further comprising an abnormality detection sensor to detect an abnormality in the overhead transport vehicle.

11. The transport system according to claim 7, wherein the peripheral device includes a processing device configured to process the article.

12. The transport system according to claim 7, wherein the peripheral device includes an overhead crane.
